(19) United States
(12) Patent Application Publication
(10) Pub. No.: US 2022/0071036 A1
(43) Pub. Date: Mar. 3, 2022

(54) COVERS FOR ELECTRONIC DEVICES

(71) Applicant: HEWLETT-PACKARD DEVELOPMENT COMPANY, L.P., SPRING, TX (US)

(72) Inventors: PO-FENG CHUANG, TAIPEI CITY (TW); KUN-HUNG LIN, TAIPEI CITY (TW); SHIH-HUA CHANG, TAIPEI CITY (TW)

(21) Appl. No.: 17/418,422

(22) PCT Filed: Feb. 1, 2019
(86) PCT No.: PCT/US2019/016234

§ 371 Date: Jun. 25, 2021

(51) Int. Cl. H05K 5/02; B05D 5/06; B05D 7/00; B44D 5/00

(52) U.S. Cl. CPC H05K 5/0243; B05D 5/062; B05D 2201/02; B44D 5/00; B05D 7/576

(57) ABSTRACT

The present disclosure is drawn to covers for electronic devices. In one example, a cover for an electronic device can include a cover substrate, a primer layer on the substrate, a radiation-cured coating layer on the primer layer, a colorant coating layer on the radiation-cured coating layer, and a clear coating layer on the colorant coating layer. The radiation-cured layer can include a three-dimensional pattern impressed into the radiation-cured coating layer. The colorant layer can conform to the three-dimensional pattern.

### BACKGROUND

The use of personal electronic devices of all types continues to increase. Cellular phones, including smartphones, have become nearly ubiquitous. Tablet computers have also become widely used in recent years. Portable laptop computers continue to be used by many for personal, entertainment, and business purposes. For portable electronic devices in particular, much effort has been expended to make these devices more useful and more powerful while at the same time making the devices smaller, lighter, and more durable. The aesthetic design of personal electronic devices is also of concern in this competitive market.

### BRIEF DESCRIPTION OF THE DRAWING

FIG. 1 is a cross-sectional view illustrating an example cover for an electronic device in accordance with examples of the present disclosure;

FIG. 2 is a top down view of an example cover for an electronic device in accordance with examples of the present disclosure;

FIG. 3 is a cross-sectional view illustrating an example electronic device in accordance with examples of the present disclosure;

FIG. 4 is a flowchart illustrating an example method of making a cover for an electronic device in accordance with examples of the present disclosure;

FIGS. 5A-5F are cross-sectional views illustrating a process of making a cover for an electronic device in accordance with examples of the present disclosure;

FIGS. 6A-6C are cross-sectional views illustrating a process of making a transparent film having a negative of a three-dimensional pattern for applying to a cover for an electronic device in accordance with examples of the present disclosure; and

FIG. 7 is a cross-sectional view illustrating a system for making a cover for an electronic device in accordance with examples of the present disclosure.

### DETAILED DESCRIPTION

The present disclosure describes covers for electronic devices. In one example, a cover for an electronic device can include a cover substrate, a primer layer on the substrate, a radiation-cured coating layer on the primer layer, a colorant coating layer on the radiation-cured coating layer, and a clear coating layer on the colorant coating layer. The radiation-cured coating layer can include a three-dimensional pattern impressed into the radiation-cured layer. The colorant coating layer can conform to the three-dimensional pattern. In a particular example, the dimensional pattern can be a crackle pattern including a network of cracks having an average width from about 1 μm to about 500 μm. In further examples, the cover substrate can include polypropylene, polycarbonate, polyethylene, polyamide, polyester, acrylonitrile-butadiene-styrene, or a combination thereof. In another example, the primer layer can include a thermoset polymer. In other examples, the radiation-cured coating layer can include UV-cured alkyd resin, UV-cured polyurethane, UV-cured epoxy, UV-cured acrylic, or a combination thereof. In further examples, the radiation-cured coating layer can have a thickness from about 10 μm to about 50 μm. In yet another example, the colorant coating layer can include a pigment and a binder. In further examples, the colorant coating layer can have a thickness from about 1 μm to about 10 μm. In a particular example, the clear coating layer can include a radiation-cured polymer.

The present disclosure also extends to electronic devices. In one example, an electronic device can include an electronic component and a cover enclosing the electronic component. The cover can include a cover substrate, a primer layer on the substrate, a radiation-cured layer on the primer layer, a colorant coating layer on the radiation-cured coating layer, and a clear coating layer on the colorant coating layer. The radiation-cured coating layer can include a three-dimensional pattern impressed into the radiation-cured coating layer. The colorant coating layer can conform to the three-dimensional pattern. In certain examples, the electronic device can be a personal computer, a laptop, a tablet computer, a smartphone, a mouse, or a keyboard.

The present disclosure also extends to methods of making covers for electronic devices. In one example, a method of making a cover for an electronic device can include applying a primer composition to a cover substrate to form a primer layer, applying a radiation-curable coating composition on the primer layer, impressing a three-dimensional pattern into the radiation-curable coating composition, applying radiation to cure the radiation-curable coating composition to form a radiation-cured coating layer, applying a colorant coating composition on the radiation-cured coating layer to form a colorant coating layer, wherein the colorant coating layer conforms to the three-dimensional pattern, and applying a clear coating layer on the colored coating layer. In certain examples, impressing the three-dimensional pattern can include pressing a transparent film including a negative relief pattern of the three-dimensional pattern against the radiation-curable coating composition. In further examples, applying radiation to cure the radiation-curable coating composition can include exposing the transparent film to UV energy while the transparent film is pressed against the radiation-curable coating composition. In a particular example, the transparent film can include a polyethylene terephthalate layer and a radiation-cured pattern layer.

In addition to the examples described above, including the covers, electronic devices, and methods, it is noted that when discussing an example, these examples can provide details relevant to other examples not explicitly mentioned. Thus, for example, in discussing a colorant coating layer related to cover, such disclosure is also relevant to and directly supported in the context of the electronic devices and methods of manufacturing described herein, and vice versa.

### Covers for Electronic Devices

In certain examples, the covers for electronic devices described herein can include a plastic cover substrate. Plastics are often used to manufacture the outer cover or housing of electronic devices because of the low cost and ease of manufacturing that plastics can provide. However, in some cases consumers may desire electronic devices having a more high-end or premium appearance. Accordingly, the covers for electronic devices described herein can include additional layers over the cover substrate to give the cover substrate a different appearance compared to covers made of plain plastic. The additional layers can include a layer of radiation-cured material having a three-dimensional pattern impressed therein. In some cases, the three-dimensional pattern can be designed to mimic the appearance of another material. The covers can also include a colorant coating layer on the radiation-cured layer and a clear coating layer on the colorant coating layer. The colorant coating layer can conform to the three-dimensional pattern impressed in the radiation-cured layer so that the three-dimensional pattern can be visible through the clear coating layer. These individual layers can be designed to contribute to the appearance of the cover. In a particular example, the three-dimensional pattern can be a crackle pattern mimicking the crackle pattern characteristic of some ceramic materials. The combination of the crackle pattern, the colorant coating layer, and the clear coating layer can closely mimic the appearance and feel of a ceramic piece.

In some particular examples, the three-dimensional pattern impressed into the radiation-cured layer can be copied from a ceramic piece or otherwise designed to have a similar appearance to a ceramic piece. The pattern can specifically mimic the appearance of a crackle or crazed finish on a ceramic piece. In the field of ceramics making, “crazing” refers to a pattern of cracks in the glaze on a ceramic piece. These cracks are caused by tensile stresses in the glaze layer that are greater than the strength of the glaze. Generally, these cracks are referred to as “crazing” when the cracks are an unintended defect in the glaze, whereas the same phenomenon is referred to as “crackle” when the effect is intentionally produced. As used herein, a “crackle pattern” used as the three-dimensional pattern in the radiation-cured layer can include any such pattern of cracks, whether mimicking the appearance of unintentional crazing or the more accentuated intentional crackle pattern produced in the field of ceramics making.

As used herein, a layer that is referred to as being “on” a lower layer can be directly applied to the lower layer, or an intervening layer or multiple intervening layers can be located between the layer and the lower layer. Generally, the covers described herein can include a cover substrate and various layers can be applied on the cover substrate. Accordingly, a layer that is “on” a lower layer can be located further from the cover substrate. For example, a primer layer can be the first layer applied directly to the substrate. A radiation-cured coating layer can then be applied on the primer layer, meaning that the radiation-cured layer is applied directly to the primer layer or that the radiation-cured layer is applied to an intervening layer on the primer layer. In some examples, the layers may be applied to an exterior surface of the cover substrate. Thus, a “higher” layer applied “on” a “lower” layer may be located farther from the cover substrate and closer to a viewer viewing the cover from the outside.

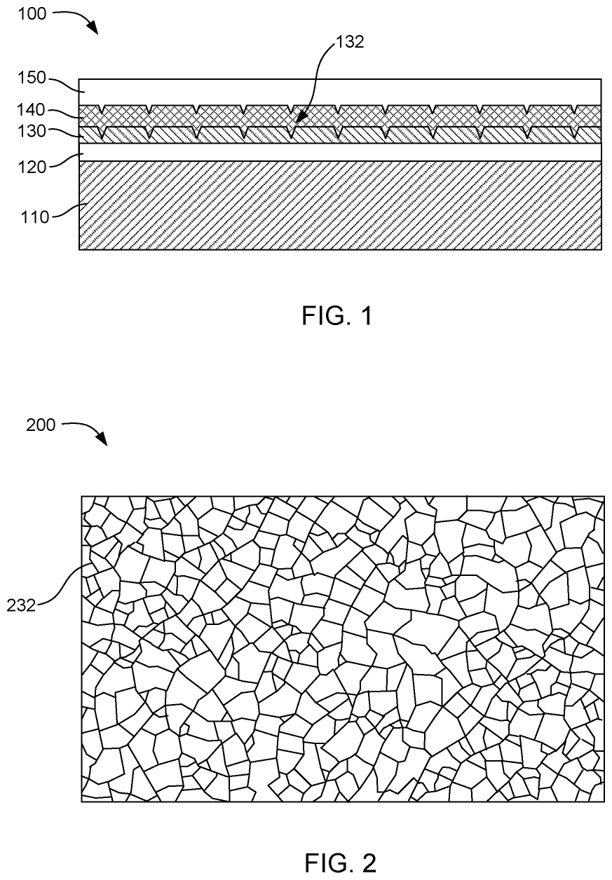

To illustrate the various layers that can be included in the covers for electronic devices described herein, FIG. 1 shows a cross-sectional schematic view of a cover 100 for an electronic device. The cover includes a cover substrate 110, a primer layer 120 on the substrate, a radiation-cured coating layer 130 on the primer layer, a colorant coating layer 140 on the radiation-cured coating layer, and a clear coating layer 150 on the colorant coating layer. The radiation-cured coating layer includes a three-dimensional pattern impressed into the radiation-cured coating layer. In this example, the three-dimensional pattern 132, which in this example includes a network of narrow cracks. The cross section of the narrow cracks is illustrated as narrow indentations in the radiation-cured coating layer. As shown in the figure, the colorant coating layer conforms to the three-dimensional pattern so that the indentations of the cracks are also visible in the colorant coating layer. The clear coating layer covers the colorant coating layer and the clear coating layer has a smooth surface. Thus, in this example the surface of the cover has a smooth feel but the network of cracks in the colorant layer is visible through the clear coating layer. Although the crack indentations in this example are shown as having a uniform size and spacing, in some examples the cracks can be more randomly distributed, with cracks of different widths extending in different directions and more randomly spaced apart.

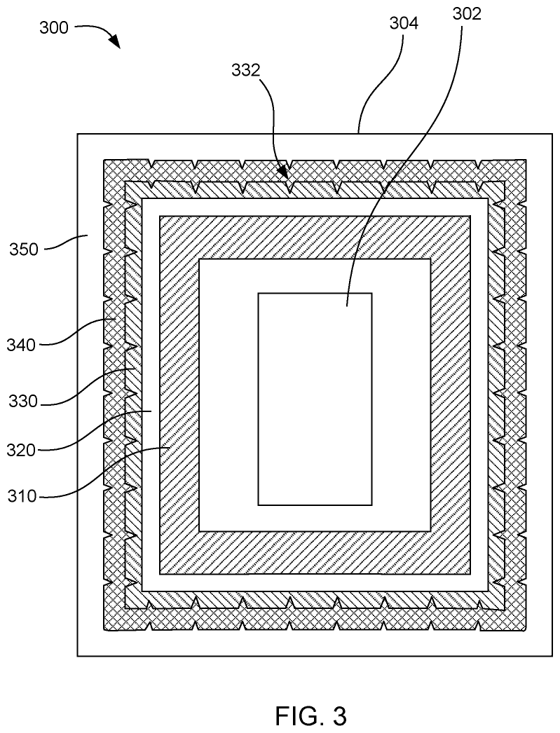

FIG. 2 shows an example cover 200 for an electronic device as viewed from above. The cover has a three-dimensional pattern 232, which in this example includes a visible crackle pattern. This pattern is designed to mimic the appearance of a crackle pattern on a ceramic piece. As shown in FIG. 1, the cover can include multiple layers on a cover substrate, including a primer layer, a radiation-cured coating layer with the impressed crackle pattern, a colorant coating layer that conforms to the crackle pattern in the radiation-cured coating layer, and a clear coating layer on the colorant coating layer. To a user, the cover can simply appear to have a smooth surface with a ceramic-like crackle pattern.

### Electronic Devices

A variety of electronic devices can be made with covers having a pattern as described herein. In various examples, such electronic devices can include various electronic components enclosed by the cover. As used herein, “encloses” or “enclosed” when used with respect to the covers enclosing electronic components can include covers completely enclosing the electronic components or partially enclosing the electronic components. Many electronic devices include openings for charging ports, input/output ports, headphone ports, and so on. Accordingly, in some examples the cover can include openings for these purposes. Certain electronic components may be designed to be exposed through an opening in the cover, such as display screens, keyboard keys, buttons, fingerprint scanners, cameras, and so on. Accordingly, the covers described herein can include openings for these components. Other electronic components may be designed to be completely enclosed, such as motherboards, batteries, sim cards, wireless transceivers, memory storage drives, and so on.

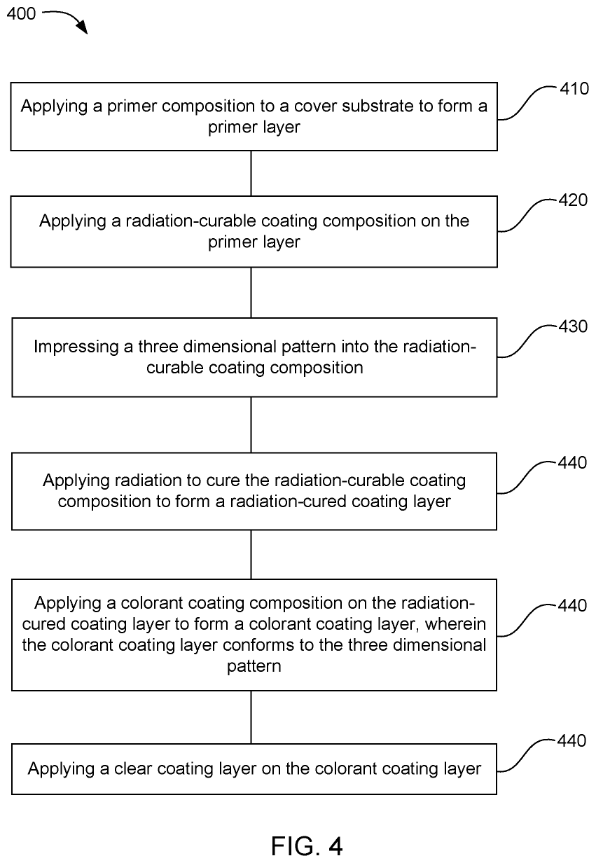

FIG. 3 shows a cross-sectional view of an example electronic device 300. The electronic device includes an electronic component 302 and a cover 304 enclosing the electronic component. The cover includes a cover substrate 310, a primer layer 320 on the substrate, a radiation-cured coating layer 330 on the primer layer, a colorant coating layer 340 on the radiation-cured coating layer, and a clear coating layer 350 on the colorant coating layer. As in the previous examples, the radiation-cured coating layer includes a three-dimensional pattern 332, which in this example is a pattern of cracks impressed into the radiation-cured coating layer.

In further examples, the electronic device can be a personal computer, a laptop, a tablet computer, a smartphone, a mouse, a keyboard, or a variety of other types of electronic devices. In various examples, the electronic device can be any type of electronic device that is commonly seen and/or handled by a user. Thus, the user can view and/or feel the particular finish provided by the cover of the electronic device.

### Methods of Making Covers for Electronic Devices

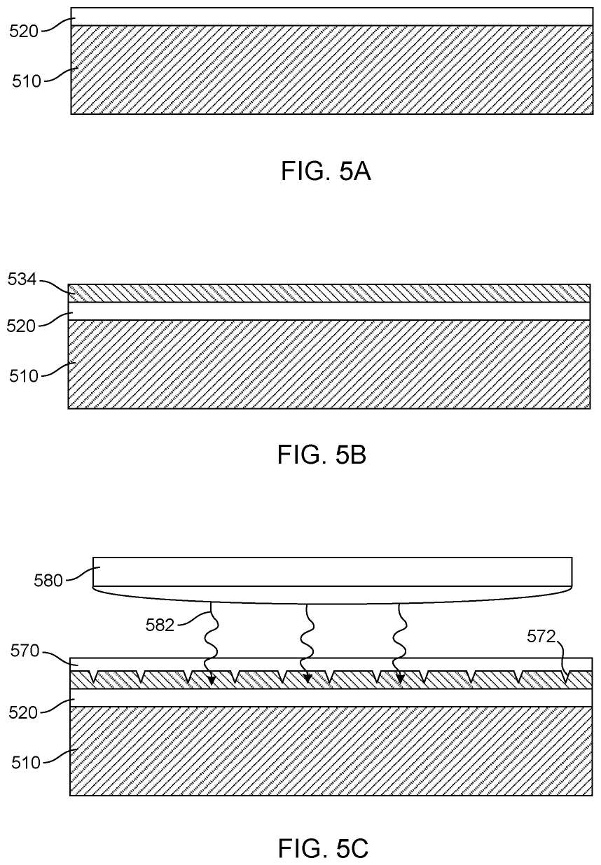

The covers described herein can be made by applying layers of various coating materials to a cover substrate. The three-dimensional pattern can be formed by pressing a pattern into a layer of radiation-curable coating material and then curing the material so that the pattern is retained in the radiation-cured coating layer. FIG. 4 is a flowchart of one example method 400 of making a cover for an electronic device. The method includes: applying a primer composition to a cover substrate to form a primer layer 410; applying a radiation-curable coating composition on the primer layer 420; impressing a three-dimensional pattern into the radiation-curable coating composition 430; applying radiation to cure the radiation-curable coating composition to form a radiation-cured coating layer 440; applying a colorant coating composition on the radiation-cured coating layer to form a colorant coating layer, wherein the colorant coating layer conforms to the three-dimensional pattern 450; and applying a clear coating layer on the colorant coating layer 460.

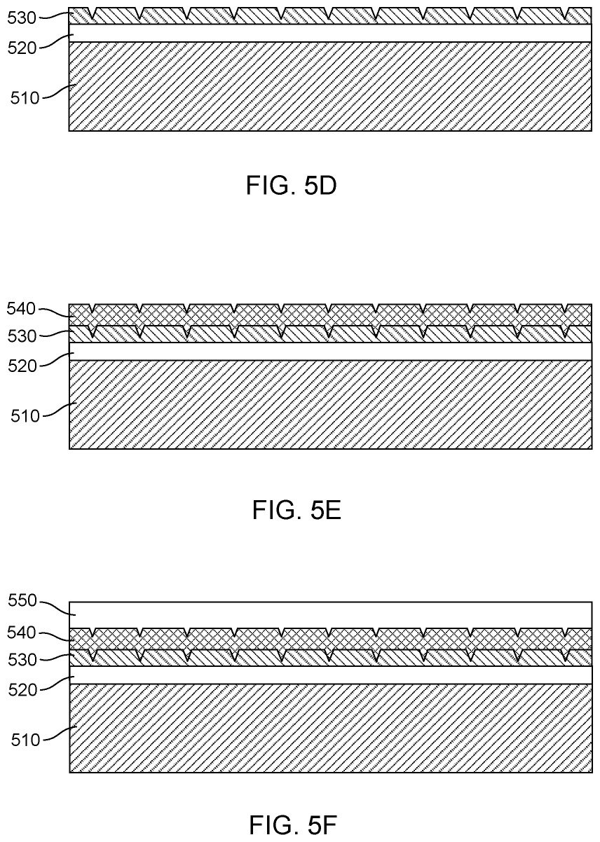

FIGS. 5A-5F illustrate the manufacture of an example cover of an electronic device. In FIG. 5A, a primer composition is applied to a cover substrate 510 to form a primer layer 520. In FIG. 5B, a radiation-curable composition 534 is applied to the primer layer. After the radiation-curable composition is applied, a transparent film 570 is pressed onto the top surface of the radiation-curable material as shown in FIG. 5C. The transparent film includes a negative relief pattern 572 of the three-dimensional pattern that is desired to be impressed in the radiation-curable material. UV energy 582 can be provided from a UV light source 580 to cure the radiation-curable material. The UV energy can pass through the transparent film to cure the radiation-curable material. After the radiation-curable material has cured, the transparent film can be removed to leave a radiation-cured coating layer 530 as shown in FIG. 5D. The radiation-cured coating layer has a three-dimensional pattern 532, including cracks impressed therein from the negative pattern on the transparent film.

After this, a colorant coating layer 540 can be applied on the radiation-cured coating layer 530 as shown in FIG. 5E. The colorant coating layer can have a thickness and other properties suitable so that the colorant coating layer conforms to the three-dimensional pattern 532 with cracks in the radiation-cured coating layer. For example, although the figure shows the colorant coating layer as having a large thickness relative to the width and depth of the indentations of the three-dimensional pattern, in some cases the thickness of the colorant coating layer can be smaller than the width and/or depth of the indentations in the pattern. A clear coating layer 550 can then be applied on the colorant coating layer as shown in FIG. 5F. In this example, the clear coating layer has a smooth top surface. However, in other examples the clear coating layer can conform to the three-dimensional pattern.

As used herein, “conform to” can include fully conforming to the three-dimensional pattern (i.e., following the contours of the pattern to produce indentations or other three-dimensional features having approximately the same depth and width as the original features of the three-dimensional pattern) or partially conforming to the three-dimensional pattern. In some examples, the colorant coating layer can partially conform to the three-dimensional pattern by having crack indentations that are shallower or narrower than the crack indentations of the three-dimensional pattern in the radiation-cured coating layer. In other examples, the colorant coating layer can partially conform to the three-dimensional pattern by following the contours of some of the cracks in the pattern while smoothing over other cracks in the pattern.

### Cover Substrates

The covers for electronic devices described herein can include a cover substrate. In some examples, the cover substrate can be formed of a plastic material. Plastic materials can include thermoplastic and thermoset polymers. In specific examples, the cover substrate can include polypropylene, polycarbonate, polyethylene, polyamide, polyester, acrylonitrile-butadiene-styrene, or a combination thereof. In other examples, the cover can be made of a metal such as aluminum, magnesium, or alloys thereof. The cover substrate can be made using any suitable manufacturing process, such as injection molding, casting, vacuum forming, stamping, milling, and so on.

Various types of electronic devices can include covers having a variety of shapes. In some examples, a cover can be made up of multiple separate cover segments, such as a top cover and a bottom cover. For example, laptop covers sometimes include four separate cover pieces forming the complete cover of the laptop. The four separate pieces of the laptop cover are often designated as cover A (back cover of the monitor portion of the laptop), cover B (front cover of the monitor portion), cover C (top cover of the keyboard portion) and cover D (bottom cover of the keyboard portion). As used herein, “cover” can refer to a single cover segment, multiple cover segments, an entire cover made up of multiple cover segments, or an entire cover made up of a single segment.

As referred to herein, the cover is an integral part of the electronic device. The term “cover” is not meant to refer to the type of removable protective cases that are often purchased separately for an electronic device (especially smartphones and tablets) and placed around the exterior of the electronic device. Rather, the cover is the exterior shell of the electronic device, within which the interior electrical components are located.

The cover substrate is not particularly limited with respect to thickness. However, the thickness of the substrate can be chosen with regard to the density of the cover substrate material (for purposes of controlling weight, for example), the hardness of the material, the malleability of the material, the desired strength of the cover, etc. In some examples, however, the thickness of the cover substrate can be from about 0.5 mm to about 2 cm, from about 1 mm to about 1.5 cm, from about 1.5 mm to about 1.5 cm, from about 2 mm to about 1 cm, from about 3 mm to about 1 cm, from about 4 mm to about 1 cm, or from about 1 mm to about 5 mm, though thicknesses outside of these ranges can be used.

### Primer Layers

In some examples, the primer layer can include a thermoset polymer, such as an epoxy. In a particular example, the primer layer can be formed by coating the cover substrate with a primer polymer composition and then curing the composition. The thickness of the primer layer can be any suitable thickness, and in some examples can be from about 1 μm to about 50 μm, from about 5 μm to about 50 μm, or from about 5 μm to about 10 μm.

The primer layer can be applied by spray coating, dip coating, or another coating method. In certain examples, the primer layer can be applied as a single layer of primer composition and then the layer can be allowed to dry and/or cure. In further examples, multiple applications of primer composition can be performed so that the primer layer is made up of multiple sub-layers. For example, a first coat of the primer composition can be applied and allowed to dry and/or cure, and then a second coat of the primer composition can be applied. In a particular example, the first coat of primer composition can be dried for about 15 minutes to about 20 minutes at about 20° C. before applying the second coat.

In further examples, the primer composition can be a thermoset paint composition. In still further examples, the primer composition can include polyacrylic, polymethacrylic, polycarbonate, polyester, cyclic olefin copolymer, or a combination thereof. In other examples, the primer composition can include a polyurethane or polyurethane copolymer. In certain examples, the polyurethane or polyurethane copolymer can be formed by polymerizing a polyisocyanate and a polyol. Non-limiting examples of polyisocyanates that can be used include toluene diisocyanate, methylene diphenyl diisocyanate, 1,6-hexamethylene diisocyanate, isophorone diisocyanate, 4,4′-diisocyanato dicyclohexylmethane, trimethylhexamethylene diisocyanate, and others. The polyol can, in some examples, be a polyether polyol or a polyester polyol having a weight average molecular weight from about 100 to about 10,000 or from about 200 to about 5,000. In certain examples, the polyol can be a diol that includes two hydroxyl groups. In further examples, the primer layer can have a thickness from about 1 μm to about 50 μm, from about 2 μm to about 25 μm, or from about 5 μm to about 15 μm.

In certain examples, the primer composition can include a moisture-cured polyurethane. Moisture-cured polyurethanes can include isocyanate-terminated prepolymers that can be cured with ambient water. In a particular example, the primer can include Airethane™ 1204 polyurethane or other Airethane™ 1000 series polyurethanes (Fairmont Industries).

### Radiation-Cured Coating Layers

The radiation-cured coating layer can be formed by applying a radiation-curable coating composition on the primer layer, impressing a three-dimensional pattern into the radiation-curable coating composition, and curing the composition. In some examples, the radiation-cured coating layer can include UV-cured alkyd resin, UV-cured polyurethane, UV-cured epoxy, UV-cured acrylic, or a combination thereof. Specific examples of UV-curable compositions that can be used in the radiation-cured coating layer include UV coatings available from PPG Industries, Inc., such as Raycron® and D&M™ UV coatings (PPG Industries, Inc., Pennsylvania); UV coatings available from Akzo Nobel such as Autoclear™ (Akzo Nobel N.V., the Netherlands). In further examples, the radiation-cured coating layer can include a radiation-curable resin such as poly(meth)acrylic, polyurethane, urethane (meth)acrylate, (meth)acrylic (meth)acrylate, epoxy (meth)acrylate, or a combination thereof.

In a particular example, the radiation-cured coating layer can have a thickness from about 10 μm to about 50 μm. In further examples, the radiation-cured coating layer can have a thickness from about 10 μm to about 30 μm. The radiation-curable composition can be applied using a suitable coating method, such as spray coating, dip coating, or another coating method. The radiation-curable composition can be cured by exposure to radiation, such as UV light at a wavelength from about 220 nm to about 320 nm. In some examples, curing can include exposing the layer to radiation energy at an intensity from about 500 mJ/cm² to about 2,000 mJ/cm² or from about 700 mJ/cm² to about 1,300 mJ/cm². In further examples, the layer can be exposed to the radiation energy for a curing time from about 5 seconds to about 60 seconds, or from about 10 seconds to about 30 seconds.

Before the radiation-curable coating composition is cured, the three-dimensional pattern can be impressed into the surface of the coating. In some examples, this can be performed by pressing a transparent film having a negative of the three-dimensional pattern onto the surface of the coating. In certain examples, the transparent film can be made up of a transparent polymeric film substrate with a layer of radiation-cured coating on a surface of the film substrate. The radiation-cured coating may, in some examples, be the same material as the radiation-cured coating layer of the cover for an electronic device. For example, UV curable clearcoat compositions can be used to form the layer of the transparent film. The negative of the three-dimensional pattern can be formed in the radiation-cured coating on the transparent film. The negative of the three-dimensional pattern can be formed by molding. In one example, a mold can be made having the three-dimensional pattern. The radiation-curable coating of the transparent film can be pressed against the mold to form a negative of the pattern in the radiation-curable coating of the transparent film. The radiation-curable coating can then be cured. The transparent film can then be ready to use by pressing the film against the radiation-curable coating on the cover to transfer the three-dimensional pattern to the cover.

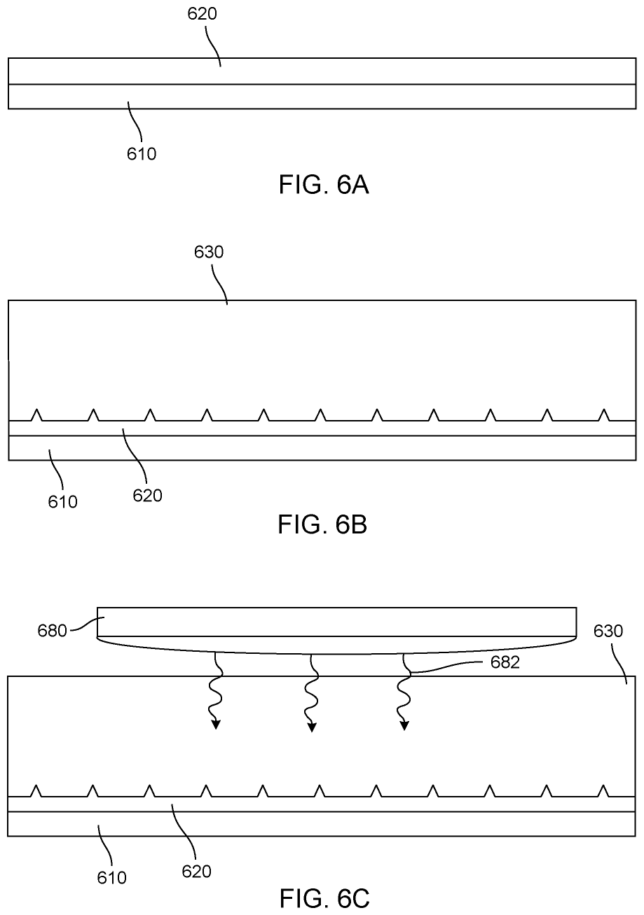

FIGS. 6A-6C show an example of the process of making a transparent film for use in manufacturing the covers for electronic devices described herein. In FIG. 6A, a polymeric film substrate 610 is coated with a radiation-curable composition 620. In some examples, the polymeric film substrate can be a polyethylene terephthalate film with a thickness of about 10 μm to about 1 mm, or from about 50 μm to about 500 μm. The layer of radiation-curable composition can have a thickness from about 10 μm to about 50 μm, or from about 25 μm to about 30 μm. In FIG. 6B, the film is pressed against a mold 630 having the three-dimensional pattern on the surface thereof. This forms to a negative of the three-dimensional pattern in the radiation curable layer of the film. The mold can be made from a transparent material such as transparent plastic. In some examples, the three-dimensional pattern can be formed on the surface of the mold by machining, laser etching, 3D printing, or another manufacturing process. In FIG. 6C, a UV light source 680 supplied UV radiation 682 to cure the radiation-curable layer of the film, forming a radiation-cured pattern layer on the polymeric film substrate. The amount of radiation applied can be similar to the amount applied to cure the radiation-curable coating composition on the cover.

As mentioned above, the transparent film can be pressed onto the radiation-curable coating on the cover for the electronic device to transfer the three-dimensional pattern to the cover. Any suitable method of pressing the transparent film onto the cover can be used. In some examples, the transparent film can be exposed to UV energy while the transparent film pressed against the radiation-curable coating composition on the cover. The UV energy can pass through the transparent film to cure the radiation-curable coating composition.

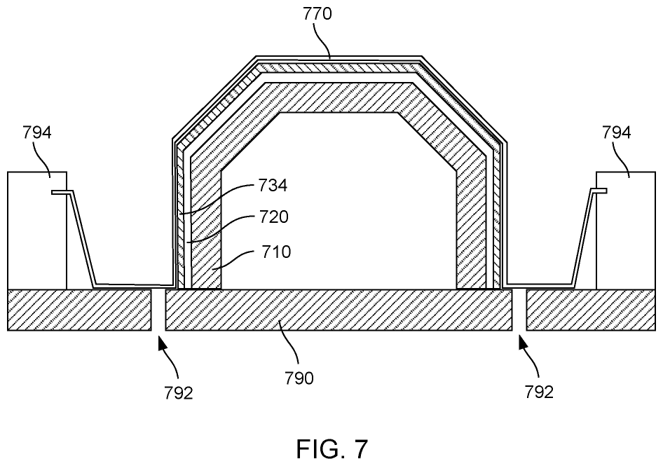

FIG. 7 shows one example of a system for pressing the transparent film against the radiation-curable coating layer on the cover of an electronic device. In this example, a cover substrate 710 having a primer layer 720 and a radiation-curable coating composition layer 734 is placed on a vacuum forming table 790. The vacuum forming table includes vacuum holes 792 and holders 794. The transparent film 770 is held by the holders. The transparent film has a negative of the three-dimensional pattern on the bottom surface of the film (the pattern is not visible in this figure as the features of the pattern are too small to clearly illustrate in this figure). Air is withdrawn through the vacuum holes, causing the transparent film to wrap around the cover. Thus, the atmospheric air pressure presses the transparent film against the layer of radiation-curable coating composition on the cover. While the vacuum is applied, UV radiation can be provided to cure the radiation-curable coating composition.

As explained above, in some examples the three-dimensional pattern can be designed to mimic the appearance of a crackle pattern on a ceramic piece. However, other designs may also be used, such as decorative designs, pictorial designs, geometric designs, or patterns designed to mimic other types of materials such as stone, cement, leather, and others. In certain examples, the three-dimensional pattern can include a network of crack indentations designed to mimic the cracks in the glaze of a ceramic piece. The cracks can have an average width from about 1 μm to about 500 μm, or from about 5 μm to about 100 μm. The crack indentations can have a crack depth from about 1 μm to about 50 μm.

The cracks can be in a network in which a crack can run across the surface until the crack meets another crack or splits into multiple cracks. In some examples, individual cracks can have a length from about 1 mm to about 20 mm, where the length is defined as the distance a single crack runs without meeting another crack or splitting into multiple cracks. In ceramic materials, because of the tensile stress in the glaze, cracks in the glaze typically continue until meeting another crack. Thus, there are very few or no cracks that terminate without either meeting another crack or splitting into multiple cracks. In some examples, the three-dimensional pattern used on the covers described herein can mimic this pattern by being devoid of or substantially devoid of cracks that terminate without meeting another crack or splitting into multiple cracks. Un-cracked areas, or cells, can be circumscribed by cracks around the perimeter of the cells. In some examples, the cells of the crackle pattern can have an average area from about 1 mm² to about 5 cm².

### Colorant Coating Layers

The colorant coating layer can be applied over the radiation-cured coating layer with a thickness sufficient to allow the colorant coating layer to conform to the three-dimensional pattern of the radiation-cured coating layer. Thus, the three-dimensional pattern can be visible in the surface of the colorant coating layer. In some examples, the colorant coating layer can have a thickness from about 1 μm to about 10 μm.

The colorant coating layer can include a pigment and a polymeric binder. Non-limiting examples of pigments used in the colorant coating layer can include carbon black, titanium dioxide, clay, mica, talc, barium sulfate, calcium carbonate, synthetic pigment, metallic powder, aluminum oxide, graphene, pearl pigment, or a combination thereof. The pigment can be present in the colorant coating layer in an amount from about 0.5 wt % to about 30 wt % with respect to dry components of the colorant coating layer, in some examples. In other examples, the amount of pigment can be from about 1 wt % to about 25 wt % or from about 2 wt % to about 15 wt % with respect to dry components of the colorant coating layer.

The polymeric binder included in the colorant coating layer with the pigment can include polyester, poly(meth)acrylic, polyurethane, epoxy, urethane (meth)acrylic, (meth)acrylic (meth)acrylate, epoxy (meth)acrylate, or a combination thereof. As used herein, a “combination” of multiple different polymers can refer to a blend of homopolymers, a copolymer made up of the different polymers or monomers thereof, or adjacent layers of the different polymers. In certain examples, the polymeric binder of the protective coating layer can have a weight-average molecular weight from about 100 g/mol to about 6,000 g/mol.

In certain examples, the colorant coating layer can be a white paint. In other examples, another color of paint can be used. In certain examples, the color can mimic a color of a ceramic piece that has been painted and/or glazed. Examples of paints that can be used include paints available from PPG Industries, Inc. and Akzo Nobel.

### Clear Coating Layers

The clear coating layer can be applied over the colorant coating layer. As mentioned above, in some examples the clear coating layer can have a smooth surface. In other examples, the clear coating layer can conform to the three-dimensional pattern such that the clear coating layer has a textured surface. The thickness of the clear coating layer can be from about 5 μm to about 30 μm, or from about 10 μm to about 20 μm.

In further examples, the clear coating layer can include a radiation-cured polymer. In certain examples, the clear coating layer can be formed of the same radiation-cured material as the radiation-cured coating layer. In some examples, the clear coating layer can be clear poly(meth)acrylic, clear polyurethane, clear urethane (meth)acrylate, clear (meth)acrylic (meth)acrylate, or clear epoxy (meth)acrylate coating. In further examples, the clear coating layer can be any of the specific UV curable materials described above for use in the is radiation-cured coating layer. The clear coating layer can also be cured using similar conditions to the radiation-cured coating layer.

### Definitions

It is noted that, as used in this specification and the appended claims, the singular forms “a,” “an,” and “the” include plural referents unless the content clearly dictates otherwise.

The term “about” as used herein, when referring to a numerical value or range, allows for a degree of variability in the value or range, for example, within 5% or other reasonable added range breadth of a stated value or of a stated limit of a range. The term “about” when modifying a numerical range is also understood to include the exact numerical value indicated, e.g., the range of about 1 wt % to about 5 wt % includes 1 wt % to 5 wt % as an explicitly supported sub-range.

As used herein, “colorant” can include dyes and/or pigments.

As used herein, “dye” refers to compounds or molecules that absorb electromagnetic radiation or certain wavelengths thereof. Dyes can impart a visible color to an ink if the dyes absorb wavelengths in the visible spectrum.

As used herein, “pigment” generally includes pigment colorants, magnetic particles, aluminas, silicas, and/or other ceramics, organo-metallics or other opaque particles, whether or not such particulates impart color. Thus, though the present description primarily exemplifies the use of pigment colorants, the term “pigment” can be used more generally to describe pigment colorants and other pigments such as organometallics, ferrites, ceramics, etc. In one specific example, however, the pigment is a pigment colorant

As used herein, a plurality of items, structural elements, compositional elements, and/or materials may be presented in a common list for convenience. However, these lists should be construed as though the individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, and also to include all the individual numerical values or sub-ranges encompassed within that range as if individual numerical values and sub-ranges are explicitly recited. For example, a layer thickness from about 0.1 μm to about 0.5 μm should be interpreted to include the explicitly recited limits of 0.1 μm to 0.5 μm, and to include thicknesses such as about 0.1 μm and about 0.5 μm, as well as subranges such as about 0.2 μm to about 0.4 μm, about 0.2 μm to about 0.5 μm, about 0.1 μm to about 0.4 μm, etc.

The following illustrates an example of the present disclosure, and relates more specifically to a method of making a cover for an electronic device. In this example, the cover is prepared as follows:
1) A cover substrate is formed by injection molding polycarbonate plastic. The cover substrate has a thickness of 1 mm.
2) An epoxy primer composition is applied at a coating thickness of 5 μm.
3) A layer of Raycron® UV coating (PPG Industries, Inc., Pennsylvania) is applied at a coating thickness of 20 μm.
4) A transparent PET film having a negative of a ceramic crackle pattern is pressed into the layer of UV coating.
5) UV light at a wavelength from 220 nm to 320 nm is applied while the transparent film is in place to cure the UV coating.
6) The transparent film is removed and a colorant coating layer of white paint is applied over the radiation-cured coating layer having the crackle pattern imprinted therein. The white paint layer conforms to the shape of the crackle pattern so that the crackle pattern is still visible on the white paint layer.
7) A clear coating layer of Raycron® UV coating is applied over the white paint layer and then cured using UV light.

It is to be understood that the above is illustrative of an application of the principles of the present disclosure. Numerous modifications and alternative compositions, methods, and systems may be devised without departing from the spirit and scope of the present disclosure. The appended claims are intended to cover such modifications and arrangements.

What is claimed is:

1. A cover for an electronic device comprising:
a cover substrate;
a primer layer on the substrate;
a radiation-cured coating layer on the primer layer, wherein the radiation-cured coating layer includes a three-dimensional pattern impressed into to the radiation-cured coating layer;
a colorant coating layer on the radiation-cured coating layer, wherein the colorant coating layer conforms to the three-dimensional pattern; and
a clear coating layer on the colorant coating layer.

2. The cover of claim 1, wherein the three-dimensional pattern is a crackle pattern comprising a network of cracks having an average width from about 1 μm to about 500 μm.

3. The cover of claim 1, wherein the cover substrate comprises polypropylene, polycarbonate, polyethylene, polyamide, polyester, acrylonitrile-butadiene-styrene, or a combination thereof.

4. The cover of claim 1, wherein the primer layer comprises a thermoset polymer.

5. The cover of claim 1, wherein the radiation-cured coating layer comprises UV-cured alkyd resin, UV-cured polyurethane, UV-cured epoxy, UV-cured acrylic, or a combination thereof.

6. The cover of claim 1, wherein the radiation-cured coating layer has a thickness from about 10 μm to about 50 μm.

7. The cover of claim 1, wherein the colorant coating layer comprises a pigment and a binder.

8. The cover of claim 1, wherein the colorant coating layer has a thickness from about 1 μm to about 10 μm.

9. The cover of claim 1, wherein the clear coating layer comprises a radiation-cured polymer.

10. An electronic device comprising:
an electronic component; and
a cover enclosing the electronic component, the cover comprising:
a cover substrate,
a primer layer on the substrate,
is a radiation-cured coating layer on the primer layer, wherein the radiation-cured coating layer includes a three-dimensional pattern impressed into the radiation-cured coating layer,
a colorant coating layer on the radiation-cured coating layer, wherein the colorant coating layer conforms to the three-dimensional pattern, and
a clear coating layer on the colorant coating layer.

11. The electronic device of claim 10, wherein the electronic device is a personal computer, a laptop, a tablet computer, a smartphone, a mouse, or a keyboard.

12. A method of making a cover for an electronic device comprising:
applying a primer composition to a cover substrate to form a primer layer;
applying a radiation-curable coating composition on the primer layer;
impressing a three-dimensional pattern into the radiation-curable coating composition;
applying radiation to cure the radiation-curable coating composition to form a radiation-cured coating layer;
applying a colorant coating composition on the radiation-cured coating layer to form a colorant coating layer, wherein the colorant coating layer conforms to the three-dimensional pattern; and
applying a clear coating layer on the colorant coating layer.

13. The method of claim 12, wherein impressing the three-dimensional pattern comprises pressing a transparent film including a negative relief pattern of the three-dimensional pattern against the radiation-curable coating composition.

14. The method of claim 13, wherein applying radiation to cure the radiation-curable coating composition comprises exposing the transparent film to UV energy while the transparent film is pressed against the radiation-curable coating composition.

15. The method of claim 13, wherein the transparent film comprises a polyethylene terephthalate layer and a radiation-cured pattern layer.
